(19) United States
(12) Patent Application Publication
(10) Pub. No.: US 2003/0030910 A1
(43) Pub. Date: Feb. 13, 2003

(54) Multi-layer antistatic/antireflective coating for video display screen with adjustable light transmission

(76) Inventor: Yueh-Ming Teng, Taoyuan (TW)

Correspondence Address: Thomas E. Hill, Esq., Emrich & Dithmar, Suite 3000, 300 South Wacker Drive, Chicago, IL, 60606, US

(21) Appl. No.: 09/925,078

(22) Filed: Aug. 8, 2001

(51) Int. Cl. B32B 15/04; H01J 29/10; C23C 14/06; C23C 14/34; G02B 1/11; G02B 1/10

(52) U.S. Cl. 359/586; 359/580

(57) ABSTRACT

A two-layer antistatic/antireflective coating technique employs a 2-step sputtering approach for first depositing an inner metallic antistatic layer on the outer surface of a glass display screen of a video display device such as a cathode ray tube (CRT), followed by deposit of an outer antireflective layer on the antistatic layer. The inner metallic antistatic layer is comprised of Ti and Cr and has a light refractive index of 2.0-2.8 and a thickness of 2-8 nm. The outer antireflective layer is comprised of SiO₂ and MgO and has a light refractive index of 1.3-1.47 and a thickness of 70-100 nm. Light transmission through the inner metallic antistatic layer may be closely adjusted as desired by precise control of the thickness of this inner layer.

### FIELD OF THE INVENTION

This invention relates generally to the application of a surface coating to a glass display screen of a video display device and is particularly directed to the deposit of a 2-layer antistatic/antireflective coating on the display screen of a video display device such as a color cathode ray tube by means of sputtering.

### BACKGROUND OF THE INVENTION

The outer surface of a display screen, or panel, of a video display device such as a cathode ray tube (CRT) is typically provided with a multi-layer coating which performs various functions. These functions include reducing light transmission through the glass display screen/outer coating combination for improved video image contrast. In addition, an inner layer of the surface coating is electrically conductive in order to shield viewers of the video display device from low frequency electromagnetic radiation and to dissipate electrostatic charge on the display panel to neutral ground. The coating also typically provides an antireflective capability to reduce light reflection from the display screen for ease in viewing a video image on the display screen.

Various approaches are employed in applying the multi-layer coating to the outer surface of a display screen. These techniques include spin coating, sometimes referred to as the wet method, vacuum vapor deposition, and sputtering. The spin coating method has been widely used with materials containing Ag—Pd or Ag—Au colloid. While the coating thus formed possesses good electrical conductivity and relatively low light reflectance, it is of relatively low quality and involves high processing costs. The spin coating approach also suffers from problems with reproducibility and control of the thickness of the coating. The vacuum vapor deposition approach involves high temperature heat treatment and is thus energy intensive and more expensive than the spin coating approach. The sputtering approach has encountered difficulties in forming at high speed a stable SiO₂ layer having a low refractive index for use in the antireflection layer. One approach for applying a light absorptive antireflective layer to a CRT display screen is disclosed in U.S. Pat. No. 5,691,044. This sputtering approach applies an inner layer of TiN to the surface of a glass substrate. The TiN layer suffers from instability at the high temperatures used for applying the multi-layer coating to the glass substrate. To improve the heat resistance of the TiN layer, an oxide barrier layer of metal nitride (TiN) is formed on the inner TiN layer. This approach requires various reacting gases such as N₂ and O₂ in the sputtering process which increases the cost and complexity of video display screen manufacture.

The present invention avoids the limitations of the prior art by providing a multilayer antistatic/antireflective coating applied by sputtering to the outer surface of a video display screen which allows for precise control over the thickness of the multilayer coating as well as its light transmission characteristics.

### OBJECTS AND SUMMARY OF THE INVENTION

Accordingly, it is an object of the present invention to provide a multi-layer antistatic/antireflective coating for a video display screen wherein the thickness of the coating may be precisely controlled for precise adjustment of the light transmitted through the coating.

It is another object of the present invention to provide an antistatic/antireflective coating for the outer surface of a video display panel having precisely controlled conductivity as low as on the order of 103 ohms and reflectivity as low as 0.7%.

The further object of the present invention is to provide an antistatic coating for the outer surface of a video display panel having a metallic composition and low conductivity, i.e., as low as 10³ ohms.

A still further object of the present invention is to provide a multi-layer antistatic/antireflective coating for a video display screen and a method of application therefor, which is metal-based and does not require the use of a reacting gas in producing and depositing the coating by sputtering.

Yet another object of the present invention is to provide a sputter coating technique for depositing a multi-layer coating on the surface of a video display screen which eliminates the need for a reactive gas and allows for close control of coating conductivity and reflectance by precise control of coating thickness.

The present invention contemplates a process for forming an antistatic/antireflective coating on an outer surface of a video display screen comprising the steps of: sputter-depositing on the outer surface of the video display screen an inner metallic antistatic layer having a precisely controlled thickness within a range of 2-8 nm, wherein a light refractive index of the inner antistatic layer is also precisely controlled within a range of 2.0-2.8; and sputter-depositing on the inner antistatic layer an outer antireflective layer having a precisely controlled thickness within a range of 70-100 nm, wherein a light refractive index of the outer antireflective layer is also precisely controlled within a range of 1.3-1.47. This invention also contemplates a multi-layer coating for a video display panel having the aforementioned composition.

### BRIEF DESCRIPTION OF THE DRAWINGS

The appended claims set forth those novel features which characterize the invention. However, the invention itself, as well as further objects and advantages thereof, will best be understood by reference to the following detailed description of a preferred embodiment taken in conjunction with the accompanying drawings, where like reference characters identify like elements throughout the various figures, in which:

FIG. 1 is a longitudinal sectional view of a CRT incorporating an antireflective/antistatic coating in accordance with the principles of the present invention;

FIG. 2 is a partial sectional view of a flat display screen having an outer surface coating comprised of an inner antistatic layer and an outer antireflective layer in accordance with the present invention; and

FIG. 3 is a simplified combined schematic and block diagram of apparatus for applying a multi-layer antireflective/antistatic coating on the outer surface of a video display screen by sputtering in accordance with one embodiment of the present invention.

### DETAILED DESCRIPTION OF THE PREFERRED EMBODIMENT

Referring to FIG. 1, there is shown a longitudinal sectional view of a color CRT 10 incorporating an antistatic/antireflective coating 32 applied by sputtering in accordance with the present invention. In the following discussion the terms “display screen”, “display panel” and “faceplate” are used interchangeably. In addition, the terms “layer” and “coating” are used synonymously. CRT 10 includes a sealed glass envelope 12 having a forward faceplate or display screen 14, an aft neck portion 18, and an intermediate funnel portion 16. Disposed on the inner surface of glass display screen 14 is a phosphor screen 24 which includes plural discrete phosphor deposits, or elements, which emit light when an electron beam is incident thereon to produce a video image on the display screen. Color CRT 10 includes three electron beams 22 directed onto and focused upon the CRT's glass display screen 14. Disposed in the neck portion 18 of the CRT's glass envelope 12 are plural electron guns 20 typically arranged in an inline array for directing the electron beams 22 onto the phosphor screen 24. The electron beams 22 are deflected vertically and horizontally in unison across the phosphor screen 24 by a magnetic deflection yoke which is not shown in the figure for simplicity. Disposed in a spaced manner from phosphor screen 24 is a shadow mask 26 having a plurality of spaced electron beam passing apertures 26a and a skirt portion 28 around the periphery thereof. The shadow mask skirt portion 28 is securely attached to a shadow mask mounting fixture 30 around the periphery of the shadow mask. The shadow mask mounting fixture 30 is attached to an inner surface of the CRT's glass envelope 12 and may include conventional attachment and positioning structures such as a mask attachment frame and a mounting spring which also are not shown in the figure for simplicity. The shadow mask mounting fixture 30 may be attached to the inner surface of the CRT's glass envelope 12 and the shadow mask 26 may be attached to the mounting fixture by conventional means such as weldments or a glass-based frit.

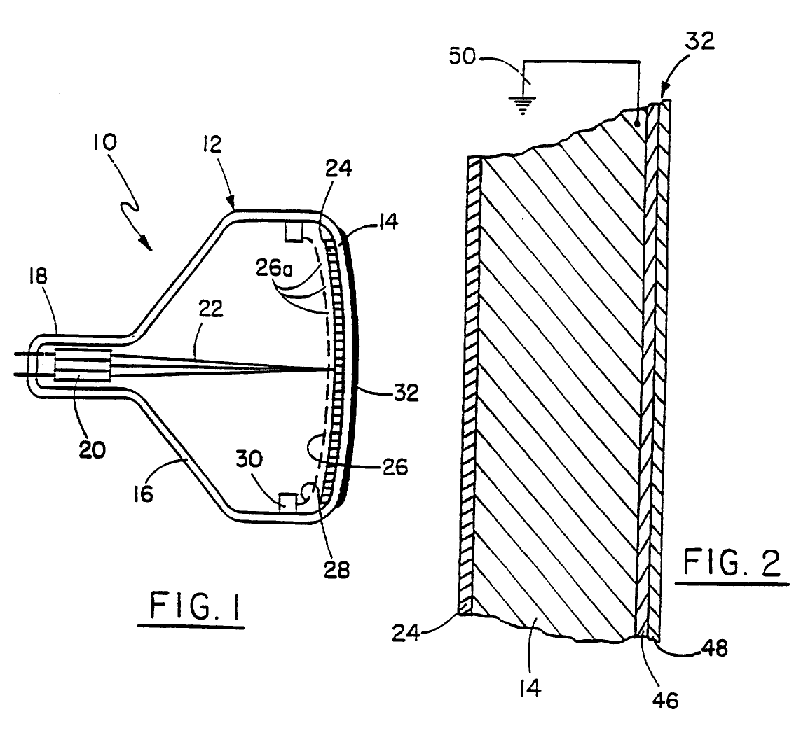

Referring to FIG. 2, there is shown a partial sectional view of a portion of the CRT's glass display screen 14 having the aforementioned phosphor layer 24 on the inner surface thereof and an outer antistatic/antireflective coating 32 on the outer surface thereof in accordance with the present invention. The glass display screen 14 of FIG. 2 is shown as being flat as the present invention is applicable with both curved display screens as shown in FIG. 1 as well as to flat display screens as shown in FIG. 2. In addition, while the present invention has been illustrated in the figures in terms of use of the outer surface of the display screen of a CRT, the present invention is not limited to use with this type of display device. For example, the antistatic/antireflective coating 32 of the present invention may be used equally as well on the outer surface of the display panel of virtually any type of self-emitting color display device, i.e., where the video image is produced by phosphor activated by energetic electrons incident thereon. Self-emitting color display devices other than CRTs include field emission displays, plasma discharge panels, vacuum fluorescent screens, and gas discharge screens. The phosphor layer 24 disposed on the inner surface of the glass display screen 14 may be in the form of a large number of discrete dots or stripes.

In accordance with the present invention, the antistatic/antireflective coating 32 includes an inner antistatic layer 46 and an outer antireflective layer 48. A conductor 50 may be attached to the inner antistatic layer 46 or to the outer surface portion of the display screen 14 for electrically coupling the display screen to neutral ground potential. In this manner, the build up of electrostatic charge on the display screen 14 is limited by discharging the electrostatic charge on the display screen to neutral ground via the electrically conductive inner antistatic layer 46.

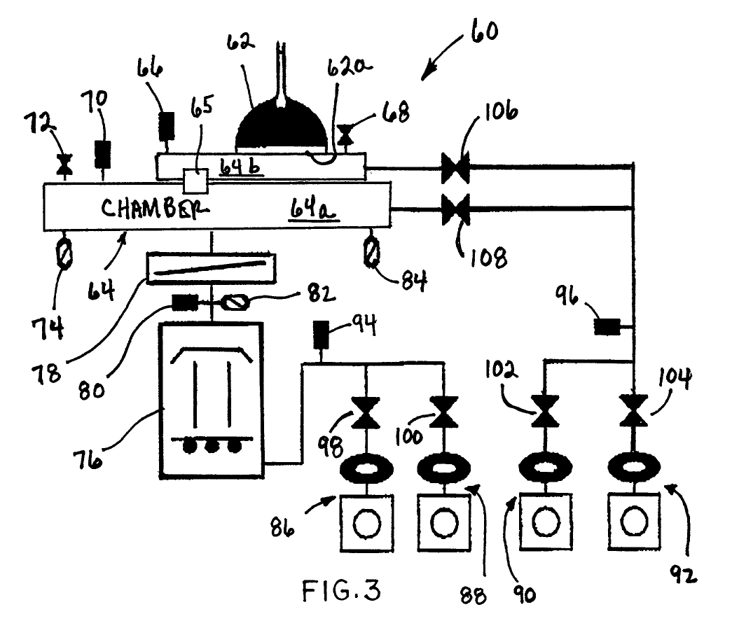

Shown in FIG. 3 is a simplified combined schematic and block diagram of a sputter deposition apparatus 60 for applying an antistatic/antireflective coating to the outer surface of the glass display screen 62a of a CRT 62 in accordance with one aspect of the present invention. Sputter deposition apparatus 60 includes a dual chamber 64 comprised of a larger chamber 64a and a smaller chamber 64b which are connected together by means of a valve 65. A conventional sputtering system (not shown for simplicity) is disposed within the vacuum chamber 64 for sputtering targets onto the outer surface of the display screen 62a of CRT 62. Each of the larger chamber 64a and the smaller chamber 64b has its own vacuum gauge and valve for controlling the respective pressures therein. Thus, the larger vacuum chamber 64a is provided with vacuum gauges 70, 74, and 84 for monitoring the pressure therein. A discharge valve 72 allows for air to enter the larger chamber 64a such as for performing maintenance on the larger chamber. Vacuum gauge 66 permits monitoring of the pressure in the smaller vacuum chamber 64b, while a discharge valve 68 allows for the entry of air into the smaller chamber for inserting or removing the display screen 62a of CRT 62. A diffusion pump 76 is connected to the combination of the larger chamber 64a and smaller chamber 64b via a gate 78. Vacuum gauges 80 and 82 are also connected between the diffusion pump 76 and the combination of the larger chamber 64a and smaller chamber 64b for monitoring the vacuum level within the diffusion pump. A pair of mechanical pumps 86 and 88 are connected to the diffusion pump 76 by means of respective valves 98 and 100. A vacuum gauge 94 is also connected between the mechanical pumps 86, 88 and the diffusion pump 76 for monitoring the pressure of the vacuum pumps. The combination of a pair of mechanical pumps 90 and 92 is coupled to the larger chamber 64a and the smaller chamber 64b by means of respective valves 108 and 106. In addition, mechanical pumps 90 and 92 are coupled to the valves 106 and 108 by means of valves 102 and 104, respectively, as well as by means of a vacuum gauge 96. Vacuum gauge 96 allows for monitoring the pressure of the vacuum pumps 90 and 92.

The sputter deposition apparatus 60 operates in the following manner. Machanical pumps 86 and 88 are turned on for pumping the diffusion pump 76 with valves 98 and 100 in the open position. Mechanical pumps 90 and 92 are turned on for pumping the larger vacuum chamber 64a with valves 102, 104 and 108 all in the open position. Valves 98, 100, 102 and 104 are always open. When the pressure of the diffusion pump 76 and the pressure in the larger vacuum chamber 64a reach the working pressure, gate 78 opens and valve 108 closes. The display screen 62a of CRT 62 is then loaded in the smaller vacuum chamber 64b and valve 106 opens for pumping the smaller vacuum chamber down to the working pressure by means of mechanical pumps 90 and 92. When the pressure within the smaller vacuum chamber 64b reaches the working pressure, valve 65 disposed between the larger and smaller vacuum chambers 64a, 64b opens to equalize the pressure between the two chambers. The sputtering system within the smaller vacuum chamber 64b then deposits the sputtering targets onto the outer surface of the CRT's display screen 62a. After coating the outer surface of the CRT's display screen 62a with the multi-layer antistatic/antireflective coating of the present invention, valve 65 closes and valve 68 opens for allowing air into the smaller vacuum chamber 64b. The CRT 62 is then unloaded, or removed, from the smaller vacuum chamber 64b and another CRT is loaded in the smaller vacuum chamber. The above described sequence of steps is then repeated for the new CRT now loaded in the small vacuum chamber 64b.

The sputter deposition apparatus 60 of FIG. 3 permits the thickness of the inner antistatic layer 46 to be controlled with great precision. The thickness of the inner antistatic layer 46 may be controlled to within 2-8 nm. The inner antistatic layer 46 preferably includes the metals Ti or Cr. By precisely controlling the thickness of the inner antistatic layer 46, its light refractive index may be controlled to be within the range of 2.0-2.8. The inner antistatic layer 46 is preferably provided with a low conductivity such as on the order of 103 ohms and a low reflectance on the order of 0.7%. The outer antireflective layer 48 preferably includes SiO₂ or MgO. The thickness of the outer antireflective layer 48 may also be precisely controlled so as to be within a range of 70-100 nm. By thus controlling the thickness of the outer antireflective layer 48, its light refractive index may be precisely controlled to be within the range of 1.3-1.47.

I claim:

1. A process for forming an antistatic/antireflective coating on an outer surface of a video display screen comprising the steps of:
sputter-depositing on the outer surface of the video display screen an inner metallic antistatic layer having a precisely controlled thickness within a range of 2-8 nm, wherein a light refractive index of said inner antistatic layer is also precisely controlled within a range of 2.0-2.8; and
sputter-depositing on said inner antistatic layer an outer antireflective layer having a precisely controlled thickness within a range of 70-100 nm, wherein a light refractive index of said outer antireflective layer is also precisely controlled within a range of 1.3-1.47.

2. The process of claim 1 wherein said inner antistatic layer includes Ti or Cr.

3. The process of claim 2 wherein said inner antistatic layer has an electrical conductivity on the order of 10³ ohms.

4. The process of claim 3 wherein said inner antistatic layer has a reflectance on the order of 0.7%.

5. The process of claim 1 wherein said outer antireflective layer includes SiO₂ or MgO.

6. A multi-layer coating for a video display panel, said coating comprising:
a inner metallic antistatic layer disposed on an outer surface of the video display panel having a precisely controlled thickness within a range of 2-8 nm, wherein a light refractive index of said inner antistatic layer is determined by the thickness of said inner antistatic layer and said light refractive index is also precisely controlled within a range of 2.0-2.8; and
an outer antireflective layer disposed on said inner antistatic layer and having a precisely controlled thickness within a range of 70-100 n, wherein a light refractive index of said outer antireflective layer is also precisely controlled within a range of 1.3-1.47.

7. The coating of claim 6 wherein said inner antistatic layer includes Ti or Cr.

8. The coating of claim 7 wherein said inner antistatic layer has an electrical conductivity on the order of 10³ ohms.

9. The coating of claim 8 wherein said inner antistatic layer has a reflectance on the order of 0.7%.

10. The coating of claim 6 wherein said outer antireflective layer includes SiO₂ or MgO.
